(19) United States
(12) Patent Application Publication
(10) Pub. No.: US 2026/0323939 A1
(43) Pub. Date: Oct. 15, 2026

(54) 3D MEMORY STRUCTURE AND A METHOD FOR FORMING THE SAME

(71) Applicant: MACRONIX INTERNATIONAL CO., LTD., Hsinchu (TW)

(72) Inventor: Pi-Shan TSENG, Tainan City (TW)

(21) Appl. No.: 19/176,695

(22) Filed: Apr. 11, 2025

(51) Int. Cl. H10B 43/27; H10B 43/30; H10D 62/40

(52) U.S. Cl. CPC H10B 43/27; H10B 43/30; H10D 62/40

(57) ABSTRACT

A 3D memory structure is provided. The 3D memory structure includes a substrate, a stack, a plurality of holes, a plurality of memory layers, a plurality of epitaxial channel layers, and a plurality of dielectric pillars. The stack is disposed on the substrate. The stack includes alternating gate layers and dielectric layers. The holes penetrate through the stack. The memory layers are disposed on sidewalls of the holes, respectively. The epitaxial channel layers are disposed on the memory layers, respectively. The epitaxial channel layers are landed on the substrate. The dielectric pillars are disposed in spaces defined by the epitaxial channel layers, respectively.

### TECHNICAL FIELD

This disclosure relates to a three-dimensional (3D) semiconductor structure and a method for forming the same. More particularly, this disclosure relates to a 3D memory structure and a method for forming the same.

### BACKGROUND

As the development of semiconductor industry, 3D structures for various electronic devices, such as memories and the like, have been proposed to increase the density and decrease the volume. To dates, new kinds of 3D structures have been developed and improvements on various 3D structures have been conducted.

### SUMMARY

This disclosure provides an improved 3D memory structure and a method for forming the same.

A 3D memory structure according to the disclosure comprises a substrate, a stack, a plurality of holes, a plurality of memory layers, a plurality of epitaxial channel layers, and a plurality of dielectric pillars. The stack is disposed on the substrate. The stack comprises alternating gate layers and dielectric layers. The holes penetrate through the stack. The memory layers are disposed on sidewalls of the holes, respectively. The epitaxial channel layers are disposed on the memory layers, respectively. The epitaxial channel layers are landed on the substrate. The dielectric pillars are disposed in spaces defined by the epitaxial channel layers, respectively.

A method for forming a 3D memory structure according to the disclosure comprises following steps. First, a stack is formed on a substrate. The stack comprises alternating first layers and second layers. A plurality of holes are formed penetrating through the stack. A plurality of memory layers are formed on sidewalls of the holes, respectively. A plurality of epitaxial channel layers are formed on the memory layers, respectively, by epitaxial growth from the substrate. A plurality of dielectric pillars are formed in spaces defined by the epitaxial channel layers, respectively.

### BRIEF DESCRIPTION OF THE DRAWINGS

FIG. 1 shows a cross-sectional view of a 3D memory structure according to the disclosure cut along a first horizontal direction.

FIG. 2 shows a cross-sectional view of the 3D memory structure according to the disclosure cut along a second horizontal direction perpendicular to the first horizontal direction.

FIG. 3 shows an exemplary circuit of the 3D memory structure according to the disclosure.

FIG. 4 shows a cross-sectional view of another 3D memory structure according to the disclosure.

FIGS. 5A-5J show various stages of a method for forming the 3D memory structure according to the disclosure.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Various embodiments will be described more fully hereinafter with reference to accompanying drawings. The description and the drawings are provided for illustrative only, and not intended to result in a limitation. For clarity, the elements may not be drawn to scale. In addition, some elements and/or reference numerals may be omitted from some drawings. It is contemplated that the elements and features of an embodiment can be beneficially incorporated in another embodiment without further recitation.

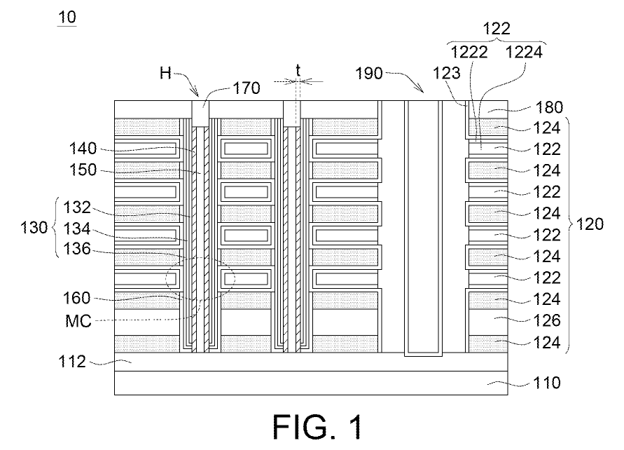

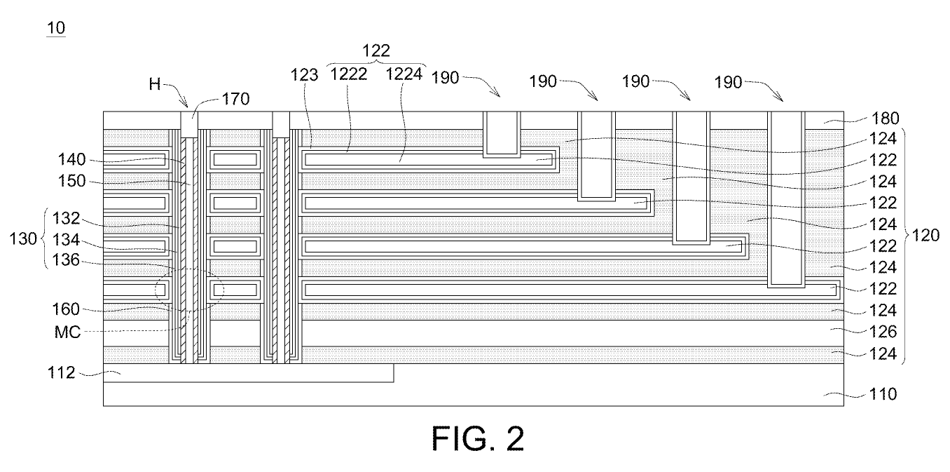

Referring to FIG. 1 and FIG. 2, a 3D memory structure 10 according to the disclosure is shown, wherein FIG. 1 shows a cross-sectional view of the 3D memory structure 10 cut along a first horizontal direction (for example, Y direction), and FIG. 2 shows another cross-sectional view of the 3D memory structure 10 cut along a second horizontal direction (for example, X direction) perpendicular to the first horizontal direction.

The 3D memory structure 10 comprises a substrate 110, a stack 120, a plurality of holes H, a plurality of memory layers 130, a plurality of epitaxial channel layers 140, and a plurality of dielectric pillars 150. The stack 120 is disposed on the substrate 110. The stack 120 comprises alternating gate layers 122 and dielectric layers 124. The holes H penetrate through the stack 120. The memory layers 130 are disposed on sidewalls of the holes H, respectively. The epitaxial channel layers 140 are disposed on the memory layers 130, respectively. The epitaxial channel layers 140 are landed on the substrate 110. The dielectric pillars 150 are disposed in spaces defined by the epitaxial channel layers 140, respectively.

More specifically, the substrate 110 can be any suitable substrate used in the semiconductor field, including but not limited to a silicon substrate. The substrate 110 can comprise a well 112, either p-type or n-type.

The stack 120 formed on the substrate 110 comprises the gate layers 122 and the dielectric layers 124. According to some embodiments, metal gates can be used. In such cases, as shown in FIG. 1 and FIG. 2, each gate layer 122 can comprise a work function layer 1222 and a metal body 1224, and high-k dielectric layers 123 can be disposed between the gate layers 122 and the dielectric layers 124. The work function layer 1222 can be formed of TiN. The metal body 1224 can be formed of W. The high-k dielectric layers 123 can be formed of oxide. However, the disclosure is not limited thereto. The high-k dielectric layers 123 can further extend on portions of sidewalls of the stack 120 except for portions of the gate layers 122. The stack 120 can further comprise a dummy layer 126 under the gate layers 122 and between bottommost two of the dielectric layers 124. The dummy layer 126 can be a grounded polysilicon layer.

The 3D memory structure 10 can further comprise a plurality of vertical dielectric layers 160 disposed on the sidewalls of the holes H, respectively. In such cases, the memory layers 130 can be disposed on the vertical dielectric layers160, respectively.

Each memory layer 130 can comprise a tunneling layer 132, a charge trapping layer 134, and a barrier layer 136. The tunneling layer 132 can be formed of oxide. The charge trapping layer 134 can be formed of nitride. The barrier layer 136 can be formed of oxide. However, the disclosure is not limited thereto.

The epitaxial channel layers 140 can be epitaxially grown from the substrate 110. More specifically, the epitaxial channel layers 140 can be single crystal layers grown from the substrate 110. The epitaxial channel layers 140 can have a thickness t from 50 Å to 100 Å. According to some embodiments, the epitaxial channel layers 140 can have a top surface higher than a top surface of an uppermost one of the gate layers 122, for example, by at least 100 Å. In cases that the substrate 110 comprises a p-type well 112 onto which the epitaxial channel layers 140 are disposed the epitaxial channel layers 140 can be n-type doped or undoped. In cases that the substrate 110 comprises a n-type well 112 onto which the epitaxial channel layers 140 are disposed, the epitaxial channel layers 140 can be p-type doped or undoped.

A plurality of memory cells MC can be defined at cross points of the gate layers 122 and the epitaxial channel layers 140.

The dielectric pillars 150 are disposed in spaces defined by the epitaxial channel layers 140. The dielectric pillars 150 can be formed of oxide, in particular high quality oxide. However, the disclosure is not limited thereto.

The 3D memory structure 10 can further comprise a plurality of plugs 170 disposed on the epitaxial channel layers 140 and the dielectric pillars 150. The plugs 170 can be formed of polysilicon. However, the disclosure is not limited thereto.

The 3D memory structure 10 can further comprise a dielectric layer 180 disposed on the stack 120, the vertical dielectric layers 160, and the memory layers 130. The dielectric layer 180 can be formed of oxide, in particular high quality oxide. However, the disclosure is not limited thereto.

The 3D memory structure 10 can further comprise a plurality of electrical connection components 190 through the dielectric layer 180 (if any) and the stack 120. The electrical connection components 190 provide electrical connection in the 3D memory structure 10. For example, the electrical connection components 190 can comprise source connection components and drain connection components described in the following paragraphs and any other electrical connection structure needed and applicable in the 3D memory structure 10.

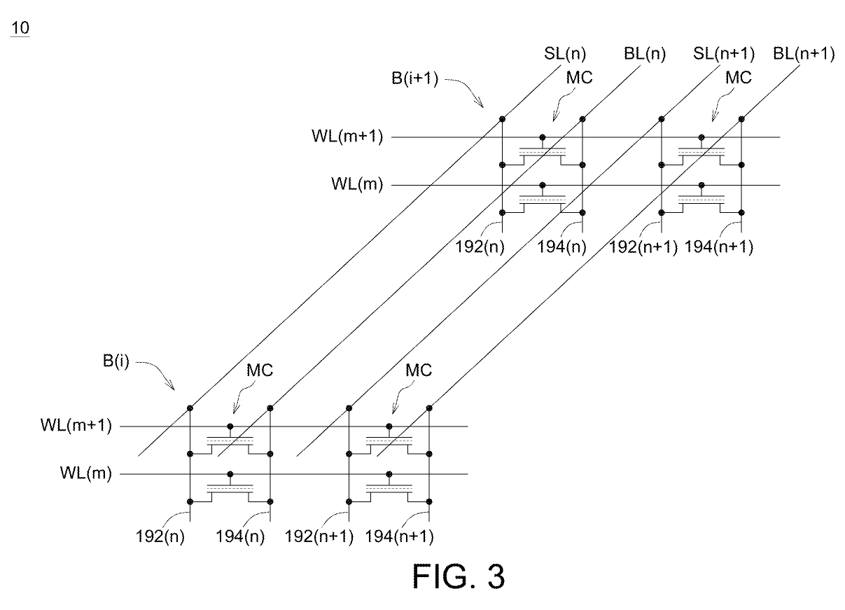

Referring to FIG. 3, an exemplary circuit of the 3D memory structure 10 is shown. In FIG. 3, two blocks B(i) and B(i+1) of the 3D memory structure are shown. Each row of the memory cells MC has a common word line. For example, in the block B(i), a m^{th} row of the memory cells MC is the memory cells MC coupled by a word line WL(m), so as to be logically arranged in a same row, but these memory cells MC are coupled to different pairs of source connection component 192(n) and drain connection component 194(n) as well as source connection component 192(n+1) and drain connection component 194(n+1). A (m+1)^{th} row of the memory cells MC is the memory cells MC coupled by a word line WL(m+1), and these memory cells MC are coupled to different pairs of source connection component 192(n) and drain connection component 194(n) as well as source connection component 192(n+1) and drain connection component 194(n+1). Similarly, in the block B(i+1), a m^{th} row of the memory cells MC is the memory cells MC coupled by a word line WL(m), and these memory cells MC are coupled to different pairs of source connection component 192(n) and drain connection component 194(n) as well as source connection component 192(n+1) and drain connection component 194(n+1). A (m+1)^{th} row of the memory cells MC is the memory cells MC coupled by a word line WL(m+1), and these memory cells MC are coupled to different pairs of source connection component 192(n) and drain connection component 194(n) as well as source connection component 192(n+1) and drain connection component 194(n+1).

Each column of the memory cells MC has a common pair of source connection component and drain connection component. For example, in the block B(i), a n^{th} column of the memory cells MC is the memory cells MC coupled by a pair of source connection component 192(n) and drain connection component 194(n), so as to be logically arranged in a same column, but these memory cells MC are coupled to different word lines WL(m) and WL(m+1). A (n+1)^{th} column of the memory cells MC is the memory cells MC coupled by a pair of source connection component 192(n+1) and drain connection component 194(n+1), and these memory cells MC are coupled to different word lines WL(m) and WL(m+1). Similarly, in the block B(i+1), a n^{th} column of the memory cells MC is the memory cells MC coupled by a pair of source connection component 192(n) and drain connection component 194(n), and these memory cells MC are coupled to different word lines WL(m) and WL(m+1) . A (n+1)^{th} column of the memory cells MC is the memory cells MC coupled by a pair of source connection component 192(n+1) and drain connection component 194(n+1), and these memory cells MC are coupled to different word lines WL(m) and WL(m+1).

The blocks B(i) and B(i+1) share source lines and bit lines. For example, a pair of source line SL(n) and bit line BL(n) are coupled to the n^{th} column of the memory cells MC in the block B(i) and the n^{th} column of the memory cells MC in the block B(i+1). A pair of source line SL(n+1) and bit line BL(n+1) are coupled to the (n+1)^{th} column of the memory cells MC in the block B(i) and the n^{th} column of the memory cells MC in the block B(i+1).

Such a 3D memory structure 10 can be a 3D NOR memory structure or a 3D AND memory structure. In such cases, top sides of the epitaxial channel layers 140 can correspond to drain sides of the memory cells MC of the 3D NOR memory structure or the 3D AND memory structure, and bottom sides of the epitaxial channel layers 140 can correspond to source sides of the memory cells MC. In addition, an bottommost one of the gate layers 122, i.e., the gate layer 122 right on the dummy layer 126, can be a source control gate, and the others of the gate layers 122 can be operation gates.

By using the epitaxial channel layers 140, cell transconductance (Gm) can be significantly improved due to the inherent properties of epitaxial structures. In addition, thin channel layers as the epitaxial channel layers 140 in this disclosure is beneficial for tightening of cell threshold voltage (Vt) distribution. As such, electrical properties of the 3D memory structure 10 can be improved by using the thin epitaxial channel layers 140. The 3D memory structure 10, either a 3D NOR memory structure or a 3D AND memory structure, can have over 16, 32, or even more gate layers 122 in the stack 110. On the other hand, the 3D memory structure 10 may be beneficial for dimension shrinkage since the thin epitaxial channel layers 140 are used.

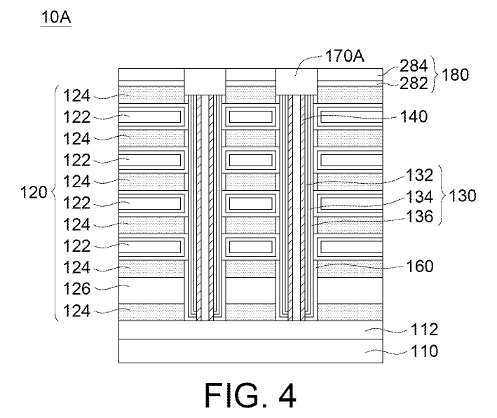

FIG. 4 shows a cross-sectional view of another 3D memory structure 10A. The 3D memory structure 10A is different from the 3D memory structure 10 by using wider pillars 170A. Each pillar 170A further extends onto the corresponding memory layers 130 and the corresponding vertical dielectric layers 160. Other details are similar to those of the 3D memory structure 10, and thus will not be repeated.

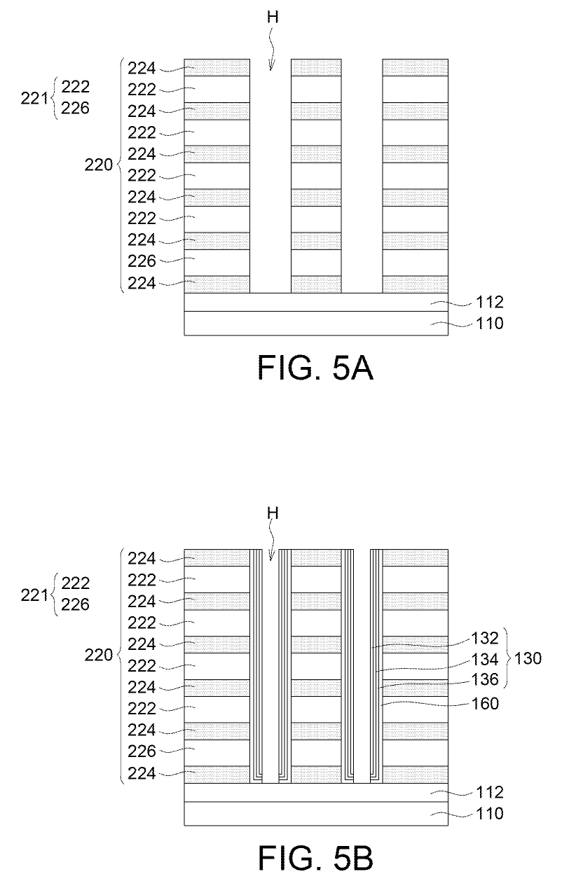

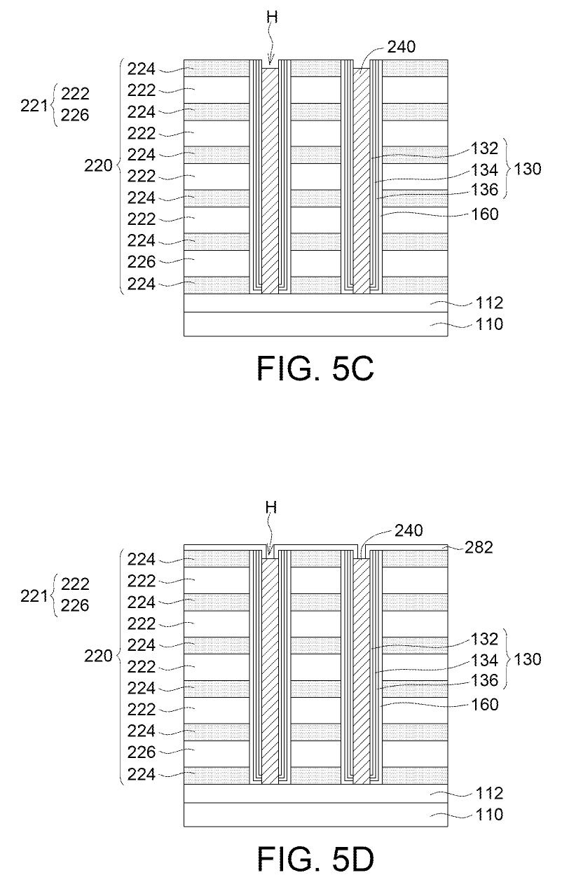

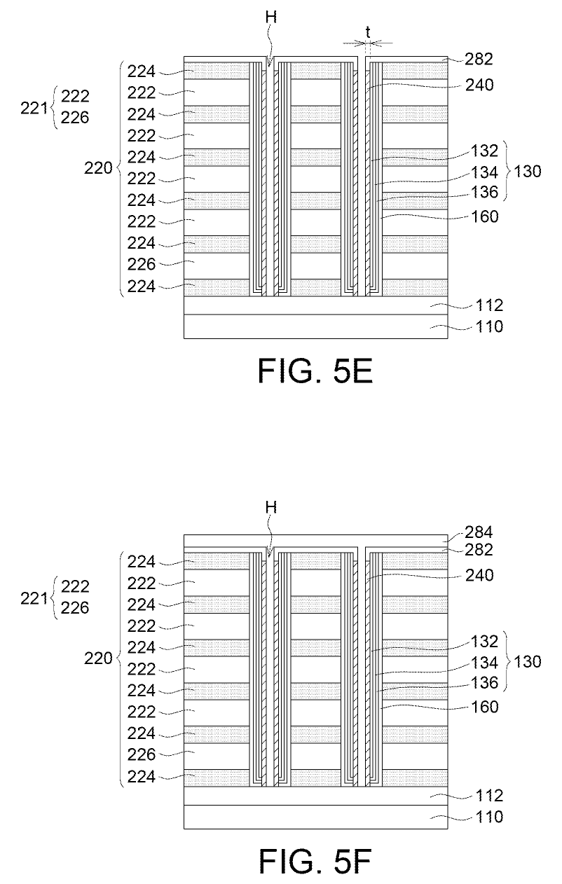

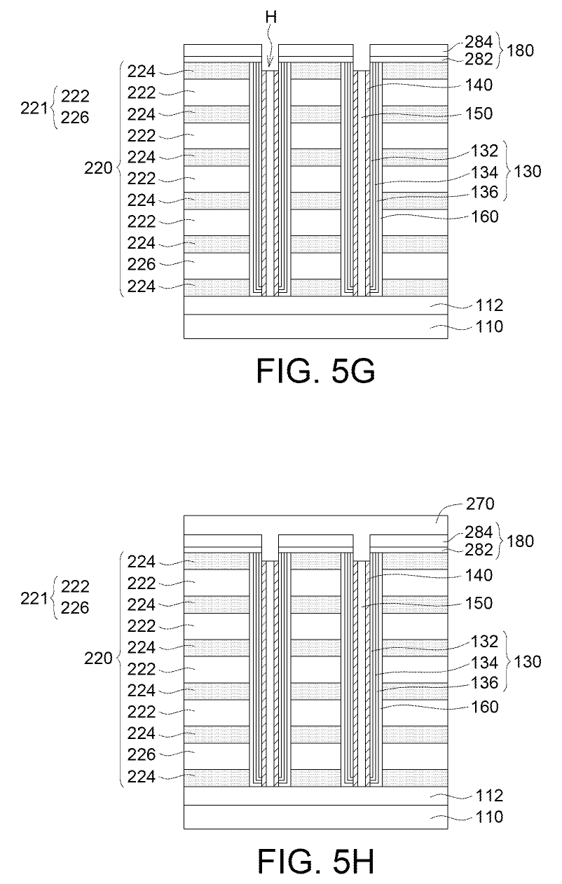

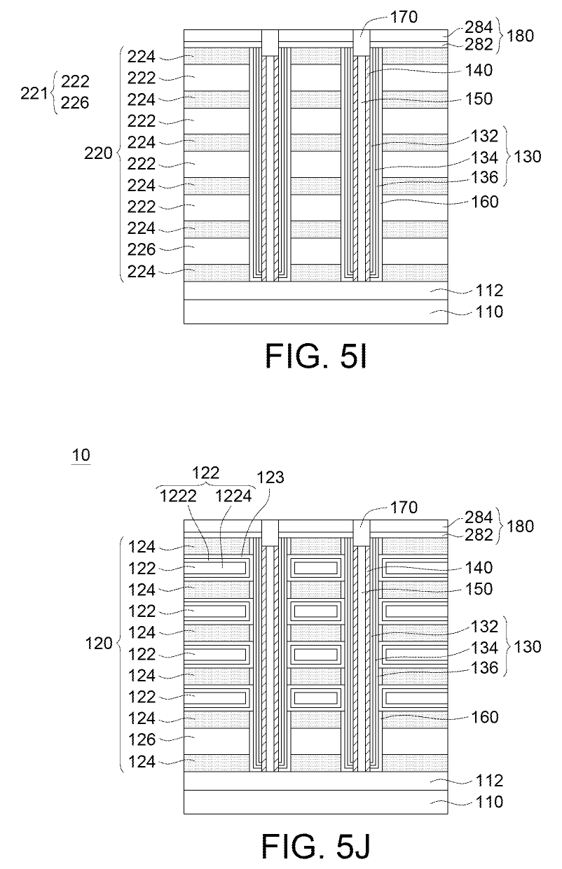

Attention is now directed to a method for forming a 3D memory structure according to the disclosure. The method comprises following steps. First, a stack is formed on a substrate. The stack comprises alternating first layers and second layers. A plurality of holes are formed penetrating through the stack. A plurality of memory layers are formed on sidewalls of the holes, respectively. A plurality of epitaxial channel layers are formed on the memory layers, respectively, by epitaxial growth from the substrate. A plurality of dielectric pillars are formed in spaces defined by the epitaxial channel layers, respectively. For example, FIGS. 5A-5J show various stages of a method for forming the 3D memory structure 10.

As shown in FIG. 5A, a stack 220 is formed on a substrate 110. The stack 220 comprises alternating first layers 221 and second layers 224. The first layers 221 comprise sacrificial layers 222. The sacrificial layers 222 can be formed of SiN. The first layers 221 can further comprise a dummy layer 226 under the sacrificial layers 222. The dummy layer 226 is the same as the dummy layer 126 as described above, and can be formed of polysilicon. The second layers 224 of the stack 220 are dielectric layers, i.e. the dielectric layers 124. A plurality of holes H are formed penetrating through the stack 220, for example, by etching.

As shown in FIG. 5B, before forming the memory layers 130, a plurality of vertical dielectric layers 160 can be conformally formed into the holes H, respectively. The vertical dielectric layers 160 can be formed of, for example, oxide. The memory layers 130 can be conformally formed on the vertical dielectric layers 160, respectively. Then, bottoms of the holes H can be opened so as to expose the corresponding portions of the substrate 110 where the channel material pillars are grown from.

Thereafter, a plurality of epitaxial channel layers 140 can be formed on the memory layers 130, respectively, by epitaxial growth from the substrate 110.

As shown in FIG. 5C, after forming the memory layers 130, channel material pillars 240 can be epitaxially grown from corresponding portions of the substrate 110 that are exposed by the holes H. More specifically, the channel material pillars 240 can be formed from the well 112. The channel material pillars 240 can be formed of silicon. According to some embodiments, the channel material pillars 240 can have a top surface higher than a top surface of an uppermost one of the sacrificial layers 222. The top surface of the channel material pillars 240 can be higher than the top surface of the uppermost one of the sacrificial layers 222 by at least 100 Å. According to some embodiments, excess channel material can be removed by etching.

As shown in FIG. 5D, a spacer layer 282 can be formed on the stack 220 and portions of the memory layers 130 that are above the channel material pillars 240 (i.e., portions of the memory layers 130 positioned a horizontal level higher than the channel material pillars 240). The spacer layer 282 can be formed of, for example, high quality oxide.

As shown in FIG. 5E, center portions of the channel material pillars 240 are removed using the spacer layer 282 as a mask, so as to form the epitaxial channel layers 140. As such, the epitaxial channel layers 140 have a same thickness as the spacer layer 282. The epitaxial channel layers 140 can have a thickness t from 50 Å to 100 Å.

Then, a plurality of dielectric pillars 150 are formed in spaces defined by the epitaxial channel layers 140, respectively.

As shown in FIG. 5F, a dielectric material 284 is provided onto the spacer layer 282 and filling into remaining spaces of the holes H. The dielectric material 284 can be, for example, high quality oxide.

As shown in FIG. 5G, portions of the spacer layer 282 and portions of the dielectric material 284 that are above the epitaxial channel layers 140 (i,e, portions of the spacer layer 282 and the dielectric material 284 positioned a horizontal level higher than the epitaxial channel layers 140) are removed, for example, by etching. Remaining portions of the dielectric material 284 in the holes H form the dielectric pillars 150. In addition, remaining portions of the dielectric material 284 on portions of the spacer layer 282 on the stack 220, together with the portions of the spacer layer 282, can form the dielectric layer 180.

As shown in FIG. 5H, a plug material 270 is provided onto the structure and filled into remaining spaces of the holes H. The plug material 270 can be, for example, polysilicon. Then, excess portions of the plug material 270 are removed, for example, by etching. As such, plugs 170 are formed on the dielectric pillars 150 and the epitaxial channel layers 140, as shown in FIG. 5I. According to some other embodiments, the plugs 170 can be further form on the memory layers 130 and the vertical dielectric layers 160. This can be achieved by adjusting the opening sizes of the holes before the stage of FIG. 5H.

As shown in FIG. 5J, the sacrificial layers 222 can be replaced with gate layers. More specifically, the sacrificial layers 222 can be removed, for example, by etching. Then, high-k dielectric layers 123, work function layer 1222, and the metal body 1224 can be formed sequentially, so as to form the 3D memory structure 10.

By applying a highly selective etching process as described above using the spacer layer 282 as the mask, the thin epitaxial channel layers 140 can be easily formed. In addition, the thickness t of the epitaxial channel layers 140 can be easily adjusted by simple change of a thickness of the spacer layer 282. As such, electrical properties of the 3D memory structure 10 can be improved with a simple process. The method according to the disclosure is also beneficial for dimension shrinkage since the thin epitaxial channel layers 140 are formed easily.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A 3D memory structure, comprising:
a substrate;
a stack disposed on the substrate, the stack comprising alternating gate layers and dielectric layers;
a plurality of holes penetrating through the stack;
a plurality of memory layers disposed on sidewalls of the holes, respectively;
a plurality of epitaxial channel layers disposed on the memory layers, respectively, the epitaxial channel layers landed on the substrate; and
a plurality of dielectric pillars disposed in spaces defined by the epitaxial channel layers, respectively.

2. The 3D memory structure according to claim 1, wherein the epitaxial channel layers are single crystal layers grown from the substrate.

3. The 3D memory structure according to claim 1, wherein the epitaxial channel layers have a thickness from 50 Å to 100 Å.

4. The 3D memory structure according to claim 1, further comprising:
a plurality of vertical dielectric layers disposed on the sidewalls of the holes, respectively;
wherein the memory layers are disposed on the vertical dielectric layers, respectively.

5. The 3D memory structure according to claim 1, wherein the stack further comprises a dummy layer under the gate layers and between bottommost two of the dielectric layers.

6. The 3D memory structure according to claim 1, wherein the epitaxial channel layers have a top surface higher than a top surface of an uppermost one of the gate layers.

7. The 3D memory structure according to claim 1,
wherein the substrate comprises a p-type well onto which the epitaxial channel layers are disposed, and the epitaxial channel layers are n-type doped or undoped; or
wherein the substrate comprises a n-type well onto which the epitaxial channel layers are disposed, and the epitaxial channel layers are p-type doped or undoped.

8. The 3D memory structure according to claim 1, wherein the 3D memory structure is a 3D NOR memory structure or a 3D AND memory structure, and wherein top sides of the epitaxial channel layers correspond to drain sides of a plurality of memory cells of the 3D NOR memory structure or the 3D AND memory structure, and bottom sides of the epitaxial channel layers correspond to source sides of the memory cells.

9. A method for forming a 3D memory structure, comprising:
forming a stack on a substrate, the stack comprising alternating first layers and second layers;
forming a plurality of holes penetrating through the stack;
forming a plurality of memory layers on sidewalls of the holes, respectively;
forming a plurality of epitaxial channel layers on the memory layers, respectively, by epitaxial growth from the substrate; and
forming a plurality of dielectric pillars in spaces defined by the epitaxial channel layers, respectively.

10. The method according to claim 9, comprising:
after forming the memory layers, epitaxially growing channel material pillars from corresponding portions of the substrate that are exposed by the holes;
forming a spacer layer on the stack and portions of the memory layers that are above the channel material pillars;
removing center portions of the channel material pillars using the spacer layer as a mask, so as to form the epitaxial channel layers.

11. The method according to claim 10, wherein the epitaxial channel layers have a same thickness as the spacer layer.

12. The method according to claim 10, wherein the epitaxial channel layers have a thickness from 50 Å to 100 Å.

13. The method according to claim 10, wherein the first layers of the stack comprise sacrificial layers, the second layers of the stack are dielectric layers, and wherein the channel material pillars have a top surface higher than a top surface of an uppermost one of the sacrificial layers.

14. The method according to claim 13, wherein the top surface of the channel material pillars is higher than the top surface of the uppermost one of the sacrificial layers by at least 100 Å.

15. The method according to claim 10, further comprising:
before forming the memory layers, conformally forming a plurality of vertical dielectric layers into the holes, respectively;
conformally forming the memory layers on the vertical dielectric layers, respectively; and
opening bottoms of the holes so as to expose the corresponding portions of the substrate where the channel material pillars are grown from.

16. The method according to claim 10, further comprising:
providing a dielectric material onto the spacer layer and filling into remaining spaces of the holes; and
removing portions of the spacer layer and portions of the dielectric material that are above the epitaxial channel layers;
wherein remaining portions of the dielectric material in the holes form the dielectric pillars.

17. The method according to claim 16, further comprising:
forming plugs on the dielectric pillars and the epitaxial channel layers.

18. The method according to claim 17, wherein the plugs further form on the memory layers and a plurality of vertical dielectric layers.

19. The method according to claim 18, wherein the first layers of the stack comprise sacrificial layers, the second layers of the stack are dielectric layers, and wherein the method further comprises:
replacing the sacrificial layers with gate layers.

20. The method according to claim 19, wherein the first layers of the stack further comprise a dummy layer under the sacrificial layers.
